(19) United States
(12) Patent Application Publication
(10) Pub. No.: US 2011/0285466 A1
(43) Pub. Date: Nov. 24, 2011

(54) POWER AMPLIFIER CIRCUIT

(75) Inventors: Takayuki Takida, Tokyo (JP); Ryota Miwa, Yokohama-shi (JP)

(73) Assignee: KABUSHIKI KAISHA TOSHIBA, Tokyo (JP)

(21) Appl. No.: 13/036,344

(22) Filed: Feb. 28, 2011

(30) Foreign Application Priority Data
May 20, 2010 (JP) 2010-116307

(51) Int. Cl. H03F 3/04

(52) U.S. Cl. 330/288

(57) ABSTRACT

A power amplifier circuit has a Gm amplifier, first and second transistors, third and fourth transistors consisting a mirror circuit, fifth and sixth transistors consisting a mirror circuit, seventh and eighth transistors consisting a mirror circuit, a ninth transistor of the first conductivity type which is connected at a first end thereof to the first power supply rail, connected at a second end thereof to a signal output terminal for outputting an amplified signal, and connected at a control terminal thereof to the inverting output terminal, and a tenth transistor of the second conductivity type connected at a first end thereof to the signal output terminal, connected at a second end thereof to the second power supply rail, and connected at a control terminal thereof to the noninverting output terminal.

### CROSS-REFERENCE TO RELATED APPLICATION

This application is based upon and claims the benefit of priority from the prior Japanese Patent Application No. 2010-116307, filed on May 20, 2010, the entire contents of which are incorporated herein by reference.

### BACKGROUND

1. Field

Embodiments described herein relate generally to a power amplifier circuit amplifying a power and outputting the amplified power.

2. Background Art

An example of a conventional power amplifier circuit (MOS type output circuit) is described in Patent Document 1. According to this power amplifier circuit, it becomes possible to suppress the change of the gate impedance of an output transistor in the state of no signal and at the time of signal input to a small value with a simple configuration and implement an analog MOS amplifier circuit which is low in distortion without increasing the chip size.

However, it cannot be said that gate impedance of a p-channel side output transistor is equal to gate impedance of an n-channel side output transistor due to action of a circuit including a MOS transistor and a resistor for determining an idle current at the time when the input signal is not supplied.

Even if drive circuits in a preceding stage respectively drive these output transistors with equal currents, therefore, transfer characteristics of this output circuit differs greatly depending upon whether a positive input signal is given or a negative input signal is given.

In other words, the conventional circuit has a problem that the symmetry between the drive circuit for the push-side (p-channel side) output transistor and the drive circuit for the pull-side (n-channel side) output transistor is poor and the symmetry of transfer characteristics of these output transistors at the time of driving is poor.

### BRIEF DESCRIPTION OF THE DRAWINGS

FIG. 1 is a circuit diagram showing an example of a configuration of a power amplifier circuit 100 according to a first embodiment of the present invention; and

FIG. 2 is a circuit diagram showing an example of a configuration of a power amplifier circuit 200 according to a second embodiment of the present invention.

### DETAILED DESCRIPTION

A power amplifier circuit according to an embodiment, includes a Gm amplifier supplied at a noninverting input terminal thereof with an input signal and supplied at an inverting input terminal thereof with a reference voltage. The power amplifier circuit includes a first current source which is connected at a first end thereof to a first power supply rail supplied with a first voltage and which outputs a first current. The power amplifier circuit includes a first transistor of a first conductivity type connected at a first end thereof to the first power supply rail. The power amplifier circuit includes a second transistor of the first conductivity type which is connected at a first end thereof to the first power supply rail and connected at a second end thereof to an inverting output terminal of the Gm amplifier, and through which a current obtained by current-mirroring a current flowing through the first transistor flows. The power amplifier circuit includes a third transistor of the first conductivity type connected at a first end thereof to a second end of the first transistor. The power amplifier circuit includes a fourth transistor of the first conductivity type which is connected at a first end thereof to the second end of the second transistor and connected at a second end thereof to a noninverting output terminal of the Gm amplifier, and through which a current obtained by current-mirroring a current flowing through the third transistor flows. The power amplifier circuit includes a second current source which is connected at a first end thereof to a second end of the third transistor and connected at a second end thereof to a second power supply rail supplied with a second voltage lower than the first voltage, and which outputs a second current equivalent to the first current. The power amplifier circuit includes a fifth transistor of a second conductivity type which is different from the first conductivity type connected at a first end thereof to a second end of the first current source. The power amplifier circuit includes a sixth transistor of the second conductivity type which is connected at a first end thereof to the second end of the second transistor and connected at a second end thereof to the second end of the fourth transistor, and through which a current obtained by current-mirroring a current flowing through the fifth transistor flows. The power amplifier circuit includes a seventh transistor of the second conductivity type connected at a first end thereof to a second end of the fifth transistor and connected at a second end thereof to the second power supply rail. The power amplifier circuit includes an eighth transistor of the second conductivity type which is connected at a first end thereof to the second end of the sixth transistor and connected at a second end thereof to the second power supply rail, and through which a current obtained by current-mirroring a current flowing through the seventh transistor flows. The power amplifier circuit includes a ninth transistor of the first conductivity type which is connected at a first end thereof to the first power supply rail, connected at a second end thereof to a signal output terminal for outputting an amplified signal, and connected at a control terminal thereof to the inverting output terminal. The power amplifier circuit includes a tenth transistor of the second conductivity type connected at a first end thereof to the signal output terminal, connected at a second end thereof to the second power supply rail, and connected at a control terminal thereof to the noninverting output terminal.

Hereafter, embodiments of the present invention will be described with reference to the drawings.

Hereafter, embodiments of a power amplifier circuit according to the present invention will be described more specifically with reference to the drawings. In the ensuing description, it is supposed that a transistor of a first conductivity type is a pMOS transistor and a transistor of a second conductivity type is an nMOS transistor. In the case where a bipolar transistor is used, however, a transistor of the first conductivity type corresponds to an PNP transistor and a transistor of the second conductivity type corresponds to a NPN transistor.

### First Embodiment

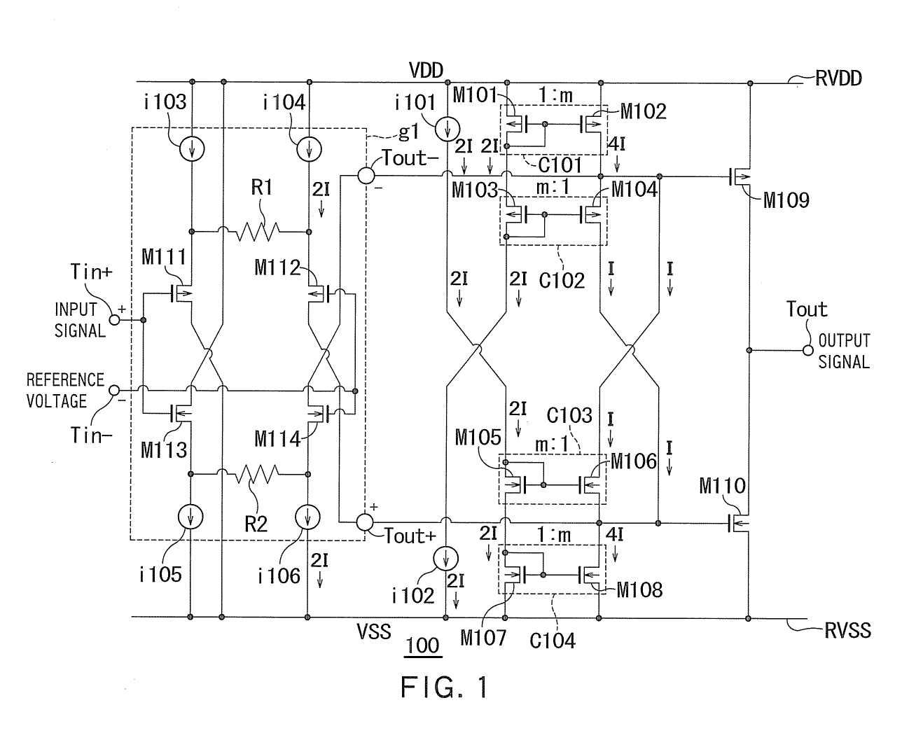

FIG. 1 is a circuit diagram showing an example of a configuration of a power amplifier circuit 100 according to a first embodiment of the present invention.

As shown in FIG. 1, the power amplifier circuit 100 includes a Gm amplifier g1, a first transistor of a first conductivity type (pMOS transistor) M101, a second transistor of the first conductivity type (pMOS transistor) M102, a third transistor of the first conductivity type (pMOS transistor) M103, a fourth transistor of the first conductivity type (pMOS transistor) M104, a fifth transistor of a second conductivity type (nMOS transistor) M105, a sixth transistor of the second conductivity type (nMOS transistor) M106, a seventh transistor of the second conductivity type (nMOS transistor) M107, an eighth transistor of the second conductivity type (nMOS transistor) M108, a ninth transistor of the first conductivity type (pMOS transistor) M109, a tenth transistor of the second conductivity type (nMOS transistor) M110, a first current source i101 and a second current source 1102.

The Gm amplifier g1 is supplied at its noninverting input terminal Tin+ with an input signal and supplied at its inverting input terminal Tin− with a reference voltage. By the way, the reference voltage is an intermediate voltage between a first voltage (for example, a power supply voltage) VDD and a second voltage (for example, ground voltage) which is lower than the first voltage VDD.

The first current source i101 is connected at its first end to a first power supply rail RVDD supplied with the first voltage VDD and adapted to output a first current I1.

The first transistor M101 is diode-connected and connected at its first end (source) to the first power supply rail RVDD.

The second transistor M102 is connected at its first end (source) to the first power supply rail RVDD and connected at its second end (drain) to an inverting output terminal Tout− of the Gm amplifier g1.

The first transistor M101 and the second transistor M102 constitute a mirror circuit C101. In other words, a current obtained by current-mirroring a current flowing through the first transistor M101 with a first mirror ratio (1:m, where m>1) flows through the second transistor M102.

The third transistor M103 is diode-connected and connected at its first end (source) to a second end (drain) of the first transistor M101.

The fourth transistor M104 is connected at first end (source) to a second end (drain) of the second transistor M102 and connected at its second end (drain) to a noninverting output terminal Tout+ of the Gm amplifier g1.

The third transistor M103 and the fourth transistor M104 constitute a mirror circuit C102. In other words, a current obtained by current-mirroring a current flowing through the third transistor M103 with a second mirror ratio (m:1) flows through the fourth transistor M104.

The second current source i102 is connected at its first end to a second end (drain) of the third transistor M103 and connected at its second end to a second power supply rail RVSS supplied with a second voltage VSS.

The second current source i102 is adapted to output a second current which is equal to the first current.

The fifth transistor M105 is diode-connected and connected at its first end (drain) to a second end of the first current source 1101.

The sixth transistor M106 is connected at its first end (drain) to the second end (drain) of the second transistor M102, and connected at its second end (source) to the second end (drain) of the fourth transistor M104.

The fifth transistor M105 and the sixth transistor M106 constitute a mirror circuit C103. In other words, a current obtained by current-mirroring a current flowing through the fifth transistor M105 with a second mirror ratio flows through the sixth transistor M106.

The seventh transistor M107 is diode-connected, connected at its first end (drain) to a second end (source) of the fifth transistor M105, and connected at its second end (source) to the second power supply rail RVSS.

The eighth transistor M108 is connected at its first end (drain) to a second end (source) of the sixth transistor M106, and connected at its second end (source) to the second power supply rail RVSS.

The seventh transistor M107 and the eighth transistor M108 constitute a mirror circuit C104. In other words, a current obtained by current-mirroring a current flowing through the seventh transistor M107 with the first mirror ratio flows through the eighth transistor M108.

The ninth transistor M109 functioning as an output transistor is connected at its first end (source) to the first power supply rail RVDD, connected at its second end (drain) to a signal output terminal Tout for outputting an amplified signal, and connected at its control terminal (gate) to the inverting output terminal Tout−.

If the current of the first transistor M101 increases, then a voltage at the second end (drain) of the first transistor M101 falls. As a result, a voltage at the second end (drain) of the second transistor M102 which is in the relation of the current mirror with the first transistor M101 also falls. Since a voltage at the control terminal (gate) of the ninth transistor M109 falls and a current flowing through the ninth transistor M109 increases, a current obtained by amplifying the current flowing through the first transistor M101 flows through the ninth transistor M109.

On the other hand, if the current flowing through the first transistor M101 decreases, then the voltage at the control terminal (gate) of the ninth transistor M109 rises and the current flowing through the ninth transistor M109 decreases. In this case as well, a current obtained by amplifying the current flowing through the first transistor M101 flows through the ninth transistor M109.

The tenth transistor M110 functioning as an output transistor is connected at its first end (drain) to the signal output terminal Tout, connected at its second end (source) to the second power supply rail RVSS, and connected at its control terminal (gate) to the noninverting output terminal Tout+.

If the current of the seventh transistor M107 increases, then a voltage at the second end (drain) of the seventh transistor M107 rises. As a result, a voltage at the second end (drain) of the eighth transistor M108 which is in the relation of the current mirror with the seventh transistor M107 also rises. Since a voltage at the control terminal (gate) of the tenth transistor M110 rises and a current flowing through the tenth transistor M110 increases, a current obtained by amplifying the current flowing through the seventh transistor M107 flows through the tenth transistor M110.

On the other hand, if the current flowing through the seventh transistor M107 decreases, then the voltage at the control terminal (gate) of the tenth transistor M110 falls and the current flowing through the tenth transistor M110 decreases. In this case as well, a current obtained by amplifying the current flowing through the seventh transistor M107 flows through the tenth transistor M110.

In this way, it is considered that in the power amplifier circuit 100 symmetry of the circuit configuration is higher as compared with the conventional technique and symmetry of the transfer characteristics is high.

As shown in FIG. 1, the Gm amplifier g1 includes, for example, an eleventh transistor of the first conductivity type (pMOS transistor) M111, a twelfth transistor of the first conductivity type (pMOS transistor) M112, a thirteenth transistor of the second conductivity type (nMOS transistor) M113, a fourteenth transistor of the second conductivity type (nMOS transistor) M114, a third current source i103, a fourth current source i104, a fifth current source i105, a sixth current source 1106, a first resistor R1, and a second resistor R2.

The third current source 1103 is connected at its first end to the first power supply rail RVDD, and adapted to output a current.

The fourth current source 1104 is connected at its first end to the first power supply rail RVDD, and adapted to output a current.

The first resistor R1 is connected between a second end of the third current source i103 and a second end of the fourth current source 1104.

The eleventh transistor M111 is connected at its first end (source) to the second end of the third current source 1103, connected at its second end (drain) to the second power supply rail VSS, and connected at its control terminal (gate) to the noninverting input terminal Tin+.

The twelfth transistor M112 is connected at its first end (source) to the second end of the fourth current source 1104, connected at its second end (drain) to the noninverting output terminal Tout+, and connected at its control terminal (gate) to the inverting input terminal Tin−.

The thirteenth transistor M113 is connected at its first end (drain) to the first power supply rail RVDD, and connected at its control terminal (gate) to the noninverting input terminal Tin+.

The fourteenth transistor M114 is connected at its first end (drain) to the inverting output terminal Tout− and connected at its control terminal (gate) to the inverting input terminal Tin−.

The second resistor R2 is connected between a second end (source) of the thirteenth transistor M113 and a second end (source) of the fourteenth transistor M114.

The fifth current source 1105 is connected at its first end to the second end (source) of the thirteenth transistor M113, connected at its second end to the second power supply rail RVSS, and adapted to output a current.

The sixth current source i106 is connected at its first end to the second end (source) of the fourteenth transistor M114, connected at its second end to the second power supply rail RVSS, and adapted to output a current.

An example of operation of the power amplifier circuit 100 having the configuration described heretofore will now be described.

For example, if an input signal having a voltage higher than the reference voltage is input to the noninverting input terminal Tin+, then a voltage at the noninverting output terminal Tout+ and a voltage at the inverting output terminal Tout− fall.

As a result, voltages at the control terminals (gates) of the ninth transistor M109 and the tenth transistor M110 fall, and consequently a voltage at the output terminal Tout rises.

On the other hand, if an input signal having a voltage lower than the reference voltage is input to the noninverting input terminal Tin+, then the voltage at the noninverting output terminal Tout+ and the voltage at the inverting output terminal Tout− rise.

As a result, the voltages at the control terminals (gates) of the ninth transistor M109 and the tenth transistor M110 rise, and consequently the voltage at the output terminal Tout falls.

In this way, the power amplifier circuit 100 is higher in symmetry of transfer characteristics as compared with the conventional technique.

It is now supposed that in the first mirror ratio (1:m) and the second mirror ratio (m:1), for example, m=2.

In this case, the first current (current value I×2) flows through the first current source i101 and the fifth and seventh transistors M105 and M107, the second current (current value I×2) flows through the second current source i102 and the first and third transistors M101 and M103, a current (current value I×4) flows through the second and eighth transistors M102 and M108, and a current (current value I) flows through the fourth and sixth transistors M104 and M106.

In addition, the current (current value I×4) flowing through the second transistor M102 becomes the sum of the current (current value I×2) flowing through the sixth current source i106, the current (current value I) flowing through the fourth transistor M104, and the current (current value I) flowing through the sixth transistor M106. The current (current value I×4) flowing through the eighth transistor M108 becomes the sum of the current (current value I×2) flowing through the fourth current source i104, the current (current value I) flowing through the fourth transistor M104, and the current (current value I) flowing through the sixth transistor M106.

In this way, the current (current value I×4) flowing through the eighth transistor M108 is greater than the current (current value I×2) flowing through the noninverting output terminal Tout+(the fourth current source i104). In the same way, the current (current value I×4) flowing through the second transistor M102 is greater than the current (current value I×2) flowing through the inverting output terminal Tout− (the sixth current source i106).

As already described, for example, a current (current value I×200) obtained by current-mirroring the current flowing through the first transistor M101 with a third mirror ratio (1:100) flows through the ninth transistor M109, and a current (current value I×200) obtained by current-mirroring the current flowing through the seventh transistor M107 with the third mirror ratio (1:100) flows through the tenth transistor M110.

Owing to the facts described heretofore, the power amplifier circuit 100 can output a signal obtained by amplifying power of the input signal while improving the symmetry of the transfer characteristics.

Especially, the power amplifier circuit 100 according to the first embodiment has a feature of excellent responsiveness because the outputs of the Gm amplifier g1 are directly connected to the gates of the ninth and tenth transistors M109 and M110.

Operation voltages of the power amplifier circuit 100 at the time when such operation is conducted will now be studied.

For example, for the power amplifier circuit 100 to conduct desired operation, the sum represented as a threshold voltage Vth1 of the ninth transistor M109+a threshold voltage Vth2 of the fourth transistor M104+a voltage drop across the second current source i102 becomes a potential difference needed between the first power supply rail RVDD and the second power supply rail RVSS. By the way, since the second current source 1102 is typically formed of a current mirror circuit, the voltage drop across the second current source 1102 becomes nearly equal to a drain-source voltage Vds.

If the power supply voltage VDD has a voltage which is equal to or higher than the threshold voltage Vth1+the threshold voltage Vth2+the drain-source voltage Vds, therefore, the power amplifier circuit 100 can conduct stable operation. For example, supposing that the threshold voltage Vth1 is 1 V, the threshold voltage Vth2 is 1 V, and the drain-source voltage Vds is 0.5 V, the power amplifier circuit 100 can conduct stable operation with the power supply voltage VDD of at least 2.5 V. In other words, the power amplifier circuit 100 can operate with a low voltage.

In the power amplifier circuit according to the first embodiment, the symmetry of the transfer characteristics can be improved as described heretofore.

In addition, in the power amplifier circuit according to the first embodiment, the number of transistor stages connected between the power supply rails can be made small and low voltage operation is possible.

### Second Embodiment

In the present second embodiment, another configuration example of a power amplifier circuit capable of improving the symmetry of the transfer characteristics will be described.

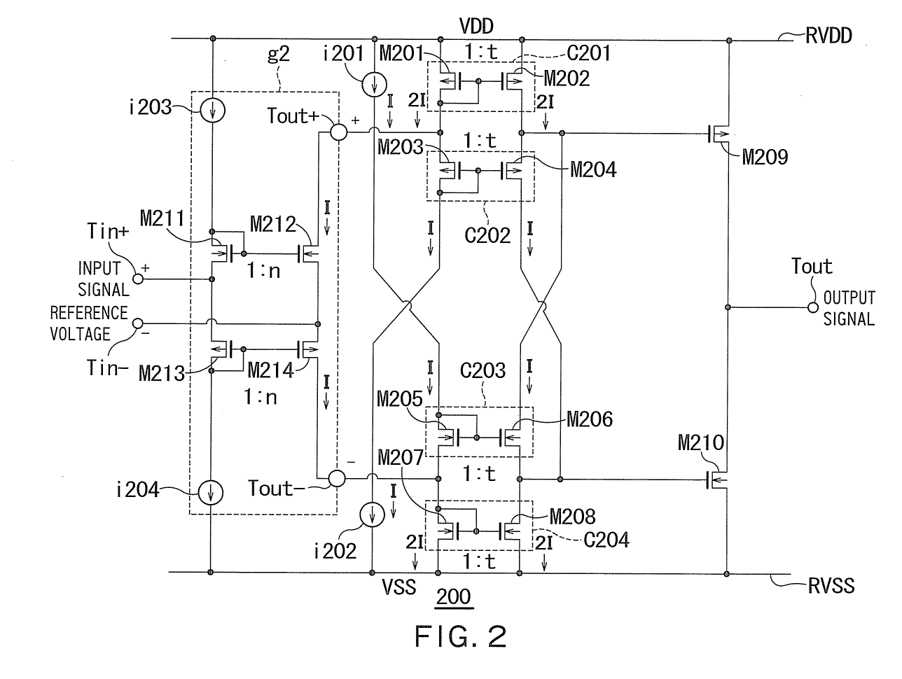

FIG. 2 is a circuit diagram showing an example of a configuration of a power amplifier circuit 200 according to a second embodiment of the present invention. In FIG. 2, the same reference numerals as those in FIG. 1 denote like components in the first embodiment.

As shown in FIG. 2, the power amplifier circuit 200 includes a Gm amplifier g2, a first current source i201, a first transistor of the first conductivity type (pMOS transistor) M201, a second transistor of the first conductivity type (pMOS transistor) M202, a third transistor of the first conductivity type (pMOS transistor) M203, a fourth transistor of the first conductivity type (pMOS transistor) M204, a fifth transistor of the second conductivity type (nMOS transistor) M205, a sixth transistor of the second conductivity type (nMOS transistor) M206, a seventh transistor of the second conductivity type (nMOS transistor) M207, an eighth transistor of the second conductivity type (nMOS transistor) M208, a ninth transistor of the first conductivity type (pMOS transistor) M209, and a tenth transistor of the second conductivity type (nMOS transistor) M210.

The Gm amplifier g2 is supplied at its noninverting input terminal Tin+ with an input signal and supplied at its inverting input terminal Tin− with a reference voltage. By the way, in the same way as the first embodiment, the reference voltage is an intermediate voltage between a first voltage (for example, a power supply voltage) VDD and a second voltage (for example, ground voltage) which is lower than the first voltage VDD.

The first current source i201 is connected at its first end to a first power supply rail RVDD supplied with the first voltage VDD and adapted to output a first current I1.

The first transistor M201 is diode-connected, connected at its first end (source) to the first power supply rail RVDD, and connected at its second end (drain) to the noninverting output terminal Tout+ of the Gm amplifier g2.

The second transistor M202 is connected at its first end (source) to the first power supply rail RVDD.

The first transistor M201 and the second transistor M202 constitute a mirror circuit C201. In other words, a current obtained by current-mirroring a current flowing through the first transistor M201 with a first mirror ratio (1:t, where t>0) flows through the second transistor M202.

The third transistor M203 is diode-connected and connected at its first end (source) to the second end (drain) of the first transistor M201.

The fourth transistor M204 is connected at its first end (source) to a second end (drain) of the second transistor M202.

The third transistor M203 and the fourth transistor M204 constitute a mirror circuit C202. In other words, a current obtained by current-mirroring a current flowing through the third transistor M203 with a second mirror ratio flows through the fourth transistor M204.

The second current source i202 is connected at its first end to a second end (drain) of the third transistor M203 and connected at its second end to a second power supply rail RVSS supplied with a second voltage VSS. The second current source i202 is adapted to output a second current I2 which is equal to the first current I1.

The fifth transistor M205 is diode-connected, connected at its first end (drain) to a second end of the first current source i201, and connected at its second end (source) to an inverting output terminal Tout− of the Gm amplifier g2.

The sixth transistor M206 is connected at its first end (drain) to the second end (drain) of the second transistor M202, and connected at its second end (source) to the second end (drain) of the fourth transistor M204.

The fifth transistor M205 and the sixth transistor M206 constitute a mirror circuit C203. In other words, a current obtained by current-mirroring a current flowing through the fifth transistor M205 with the first mirror ratio flows through the sixth transistor M206.

The seventh transistor M207 is diode-connected, connected at its first end (drain) to a second end (source) of the fifth transistor M205, and connected at its second end (source) to the second power supply rail RVSS.

The eighth transistor M208 is connected at its first end (drain) to a second end (source) of the sixth transistor M206, and connected at its second end (source) to the second power supply rail RVSS.

The seventh transistor M207 and the eighth transistor M208 constitute a mirror circuit C204. In other words, a current obtained by current-mirroring a current flowing through the seventh transistor M207 with the first mirror ratio flows through the eighth transistor M208.

The ninth transistor M209 functioning as an output transistor is connected at its first end (source) to the first power supply rail RVDD, connected at its second end (drain) to a signal output terminal Tout for outputting an amplified signal, and connected at its control terminal (gate) to the second end (drain) of the second transistor M202.

If the current of the first transistor M201 increases, then a voltage at the second end (drain) of the first transistor M201 falls. As a result, a voltage at the second end (drain) of the second transistor M202 which is in the relation of the current mirror with the first transistor M201 also falls. Since a voltage at the control terminal (gate) of the ninth transistor M209 falls and a current flowing through the ninth transistor M209 increases, a current obtained by amplifying the current flowing through the first transistor M201 flows through the ninth transistor M209.

On the other hand, if the current flowing through the first transistor M201 decreases, then the voltage at the control terminal (gate) of the ninth transistor M209 rises and the current flowing through the ninth transistor M209 decreases. A current obtained by amplifying the current flowing through the first transistor M201 flows through the ninth transistor M209.

The tenth transistor M210 functioning as an output transistor is connected at its first end (drain) to the signal output terminal Tout, connected at its second end (source) to the second power supply rail RVSS, and connected at its control terminal (gate) to the first end (drain) of the eighth transistor M208.

If the current of the seventh transistor M207 increases, then a voltage at the second end (drain) of the seventh transistor M207 rises. As a result, a voltage at the second end (drain) of the eighth transistor M208 which is in the relation of the current mirror with the seventh transistor M207 also rises. Since a voltage at the control terminal (gate) of the tenth transistor M210 rises and a current flowing through the tenth transistor M210 increases, a current obtained by amplifying the current flowing through the seventh transistor M207 flows through the tenth transistor M210.

On the other hand, if the current flowing through the seventh transistor M207 decreases, then the voltage at the control terminal (gate) of the tenth transistor M210 falls and the current flowing through the tenth transistor M210 decreases. In this case as well, a current obtained by amplifying the current flowing through the seventh transistor M207 flows through the tenth transistor M210.

In this way, it is considered that in the power amplifier circuit 200 symmetry of the circuit configuration is higher as compared with the conventional technique and symmetry of the transfer characteristics is high.

As shown in FIG. 2, the Gm amplifier g2 includes, for example, a third current source i203, a fourth current source 1204, an eleventh transistor of the second conductivity type (nMOS transistor) M211, a twelfth transistor of the second conductivity type (nMOS transistor) M212, a thirteenth transistor of the first conductivity type (pMOS transistor) M213, and a fourteenth transistor of the first conductivity type (pMOS transistor) M214.

The third current source i203 is connected at its first end to the first power supply rail RVDD, and adapted to output a current.

The eleventh transistor M211 is diode-connected, connected at its first end (drain) to a second end of the third current source i203, and connected at its second end (source) to the noninverting input terminal Tin+.

The twelfth transistor M212 is connected at its first end (drain) to the noninverting output terminal Tout+, connected at its second end (source) to the inverting input terminal Tin−, and connected at its control terminal (gate) to a control terminal (gate) of the eleventh transistor M211.

The eleventh transistor M211 and the twelfth transistor M212 constitute a mirror circuit. In other words, a current obtained by current-mirroring a current flowing through the eleventh transistor M211 with a mirror ratio (1:n, where n>0) flows through the twelfth transistor M212.

The thirteenth transistor M213 is diode-connected and connected at its first end (source) to the noninverting input terminal Tin+.

The fourteenth transistor M214 is connected at its first end (source) to the inverting input terminal Tin−, connected at its second end (drain) to the inverting output terminal Tout−, and connected at its control terminal (gate) to a control terminal (gate) of the thirteenth transistor M213.

The thirteenth transistor M213 and the fourteenth transistor M214 constitute a mirror circuit. In other words, a current obtained by current-mirroring a current flowing through the thirteenth transistor M213 with the mirror ratio (1:n, where n>j) flows through the fourteenth transistor M214.

The fourth current source i204 is connected at its first end to the second end (drain) of the thirteenth transistor M213, connected at its second end to the second power supply rail RVSS, and adapted to output a current.

An example of operation of the power amplifier circuit 200 having the configuration described heretofore will now be described.

For example, if an input signal having a voltage higher than the reference voltage is input to the noninverting input terminal Tin+, then a voltage at the noninverting output terminal Tout+ and a voltage at the inverting output terminal Tout− fall.

As a result, the voltages at the second ends (drains) of the first and second transistors M201 and M202 which constitute the first mirror circuit C201 fall. In addition, the voltages at the first ends (drains) of the seventh and eighth transistors M207 and M208 which constitute the fourth mirror circuit C204 fall.

Therefore, the voltages at the control terminals (gates) of the ninth transistor M209 and the tenth transistor M210 fall, and consequently a voltage at the output terminal Tout rises (and becomes closer to the power supply voltage VDD).

On the other hand, if an input signal having a voltage lower than the reference voltage is input to the noninverting input terminal Tin+, then the voltage at the noninverting output terminal Tout+ and the voltage at the inverting output terminal Tout− rise.

As a result, the voltages at the second ends (drains) of the first and second transistors M201 and M202 which constitute the first mirror circuit C201 rise. In addition, the voltages at the first ends (drains) of the seventh and eighth transistors M207 and M208 which constitute the fourth mirror circuit C204 rise.

Therefore, the voltages at the control terminals (gates) of the ninth transistor M209 and the tenth transistor M210 rise, and consequently the voltage at the output terminal Tout falls.

In this way, the power amplifier circuit 200 is higher in symmetry of transfer characteristics as compared with the conventional technique.

It is now supposed that in the first mirror ratio (1:t), for example, t=1.

In this case, the first current (current value I) flows through the first current source i201 and the fifth transistor M205, the second current (current value I) flows through the second current source i202 and third transistor M203, a current (current value I×2) flows through the second and eighth transistors M202 and M208, and a current (current value I) flows through the fourth and sixth transistors M204 and M206.

In addition, the current (current value I×2) flowing through the first transistor M201 becomes the sum of the current (current value I) flowing through the third transistor M203 and the current (current value I) flowing through the twelfth transistor M212. The current (current value I×2) flowing through the seventh transistor M207 becomes the sum of the current (current value I) flowing through the fifth transistor M205 and the current (current value I) flowing through the fourteenth transistor M214.

In addition, the current (current value I×2) flowing through the second transistor M202 becomes the sum of the current (current value I) flowing through the fourth transistor M204 and the current (current value I) flowing through the sixth transistor M206. The current (current value I×2) flowing through the eighth transistor M208 becomes the sum of the current (current value I) flowing through the fourth transistor M204 and the current (current value I) flowing through the sixth transistor M206.

In this way, the current (current value I×2) flowing through the first transistor M201 is greater than the current (current value I) flowing through the noninverting output terminal Tout+ (the twelfth transistor M212). In the same way, the current (current value I×2) flowing through the seventh transistor M207 is greater than the current (current value I) flowing through the inverting output terminal Tout− (the fourteenth transistor M214).

As already described, a current obtained by amplifying the current flowing through the first transistor M210 flows through the ninth transistor M209, and a current obtained by amplifying the current flowing through the seventh transistor M207 flows through the tenth transistor M210.

Owing to the facts described heretofore, the power amplifier circuit 200 can output a signal obtained by amplifying power of the input signal while improving the symmetry of the transfer characteristics.

Operation voltages of the power amplifier circuit 200 at the time when such operation is conducted will now be studied.

For example, for the power amplifier circuit 200 to conduct desired operation, the sum represented as a threshold voltage Vth1 of the first transistor M201+a drain-source voltage Vds1 of the twelfth transistor M212+a drain-source voltage Vds2 of the fourteenth transistor M214+a threshold voltage Vth2 of the seventh transistor M207 becomes a potential difference needed between the first power supply rail RVDD and the second power supply rail RVSS.

If the power supply voltage VDD has a voltage which is equal to or higher than the threshold voltage Vth1+the threshold voltage Vth2+the drain-source voltage Vds1+the drain-source voltage Vds2, therefore, the power amplifier circuit 200 can conduct stable operation. For example, supposing that the threshold voltage Vth1 and Vth2 is 1 V, and the drain-source voltage Vds1 and Vds2 is 0.5 V, the power amplifier circuit 200 can conduct stable operation with the power supply voltage VDD of at least 3.0 V. In other words, the power amplifier circuit 200 can operate with a low voltage.

In the power amplifier circuit according to the present second embodiment, the symmetry of the transfer characteristics can be improved as described heretofore.

In addition, in the power amplifier circuit according to the present second embodiment, the number of transistor stages connected between the power supply rails can be made small and low voltage operation is possible.

In the embodiments, the case where MOS transistors are adopted as transistors has been described. In this case, the control terminal corresponds to the gate, and the first end and the second end correspond to the source and drain or the drain and source.

However, similar actions and effects can be obtained even if bipolar transistors are used as the transistors. In this case, the control terminal corresponds to the base and the first end and the second end correspond to the emitter and collector or the collector and emitter.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A power amplifier circuit comprising:
a Gm amplifier supplied at a noninverting input terminal thereof with an input signal and supplied at an inverting input terminal thereof with a reference voltage;
a first current source which is connected at a first end thereof to a first power supply rail supplied with a first voltage and which outputs a first current;
a first transistor of a first conductivity type connected at a first end thereof to the first power supply rail;
a second transistor of the first conductivity type which is connected at a first end thereof to the first power supply rail and connected at a second end thereof to an inverting output terminal of the Gm amplifier, and through which a current obtained by current-mirroring a current flowing through the first transistor flows;
a third transistor of the first conductivity type connected at a first end thereof to a second end of the first transistor;
a fourth transistor of the first conductivity type which is connected at a first end thereof to the second end of the second transistor and connected at a second end thereof to a noninverting output terminal of the Gm amplifier, and through which a current obtained by current-mirroring a current flowing through the third transistor flows;
a second current source which is connected at a first end thereof to a second end of the third transistor and connected at a second end thereof to a second power supply rail supplied with a second voltage lower than the first voltage, and which outputs a second current equivalent to the first current;
a fifth transistor of a second conductivity type which is different from the first conductivity type connected at a first end thereof to a second end of the first current source;
a sixth transistor of the second conductivity type which is connected at a first end thereof to the second end of the second transistor and connected at a second end thereof to the second end of the fourth transistor, and through which a current obtained by current-mirroring a current flowing through the fifth transistor flows;
a seventh transistor of the second conductivity type connected at a first end thereof to a second end of the fifth transistor and connected at a second end thereof to the second power supply rail;
an eighth transistor of the second conductivity type which is connected at a first end thereof to the second end of the sixth transistor and connected at a second end thereof to the second power supply rail, and through which a current obtained by current-mirroring a current flowing through the seventh transistor flows;
a ninth transistor of the first conductivity type which is connected at a first end thereof to the first power supply rail, connected at a second end thereof to a signal output terminal for outputting an amplified signal, and connected at a control terminal thereof to the inverting output terminal; and
a tenth transistor of the second conductivity type connected at a first end thereof to the signal output terminal, connected at a second end thereof to the second power supply rail, and connected at a control terminal thereof to the noninverting output terminal.

2. The power amplifier circuit according to claim 1, wherein
a current, obtained by current-mirroring a current flowing through the first transistor with a first mirror ratio, flows through the second transistor,
a current, obtained by current-mirroring a current flowing through the third transistor with a second mirror ratio, flows through the fourth transistor,
a current, obtained by current-mirroring a current flowing through the fifth transistor with the second mirror ratio, flows through the sixth transistor, and
a current, obtained by current-mirroring a current flowing through the seventh transistor with the first mirror ratio, flows through the eighth transistor.

3. The power amplifier circuit according to claim 1, wherein
the current flowing through the second transistor is greater than the current flowing through the inverting output terminal, and
the current flowing through the eighth transistor is greater than the current flowing through the noninverting output terminal.

4. The power amplifier circuit according to claim 2, wherein
the current flowing through the second transistor is greater than the current flowing through the inverting output terminal, and
the current flowing through the eighth transistor is greater than the current flowing through the noninverting output terminal.

5. The power amplifier circuit according to claim 1, wherein the Gm amplifier comprises:
a third current source connected at a first end thereof to the first power supply rail, and adapted to output a current,
a fourth current source connected at a first end thereof to the first power supply rail, and adapted to output a current,
a first resistor connected between a second end of the third current source and a second end of the fourth current source,
an eleventh transistor of the first conductivity type connected at a first end thereof to the second end of the third current source, connected at a second end thereof to the second power supply rail, and connected at a control terminal thereof to the noninverting input terminal,
a twelfth transistor of the first conductivity type connected at a first end thereof to the second end of the fourth current source, connected at a second end thereof to the noninverting output terminal, and connected at a control terminal thereof to the inverting input terminal,
a thirteenth transistor of the second conductivity type connected at a first end thereof to the first power supply rail, and connected at a control terminal thereof to the noninverting input terminal,
a fourteenth transistor of the second conductivity type connected at a first end thereof to the inverting output terminal and connected at a control terminal thereof to the inverting input terminal,
a second resistor connected between a second end of the thirteenth transistor and a second end of the fourteenth transistor,
a fifth current source connected at a first end thereof to the second end of the thirteenth transistor, connected at a second end thereof to the second power supply rail, and adapted to output a current, and
a sixth current source connected at a first end thereof to the second end of the fourteenth transistor, connected at a second end thereof to the second power supply rail, and adapted to output a current.

6. The power amplifier circuit according to claim 2, wherein the Gm amplifier comprises:
a third current source connected at a first end thereof to the first power supply rail, and adapted to output a current,
a fourth current source connected at a first end thereof to the first power supply rail, and adapted to output a current,
a first resistor connected between a second end of the third current source and a second end of the fourth current source,
an eleventh transistor of the first conductivity type connected at a first end thereof to the second end of the third current source, connected at a second end thereof to the second power supply rail, and connected at a control terminal thereof to the noninverting input terminal,
a twelfth transistor of the first conductivity type connected at a first end thereof to the second end of the fourth current source, connected at a second end thereof to the noninverting output terminal, and connected at a control terminal thereof to the inverting input terminal,
a thirteenth transistor of the second conductivity type connected at a first end thereof to the first power supply rail, and connected at a control terminal thereof to the noninverting input terminal,
a fourteenth transistor of the second conductivity type connected at a first end thereof to the inverting output terminal and connected at a control terminal thereof to the inverting input terminal,
a second resistor connected between a second end of the thirteenth transistor and a second end of the fourteenth transistor,
a fifth current source connected at a first end thereof to the second end of the thirteenth transistor, connected at a second end thereof to the second power supply rail, and adapted to output a current, and
a sixth current source connected at a first end thereof to the second end of the fourteenth transistor, connected at a second end thereof to the second power supply rail, and adapted to output a current.

7. The power amplifier circuit according to claim 3, wherein the Gm amplifier comprises:
a third current source connected at a first end thereof to the first power supply rail, and adapted to output a current,
a fourth current source connected at a first end thereof to the first power supply rail, and adapted to output a current,
a first resistor connected between a second end of the third current source and a second end of the fourth current source,
an eleventh transistor of the first conductivity type connected at a first end thereof to the second end of the third current source, connected at a second end thereof to the second power supply rail, and connected at a control terminal thereof to the noninverting input terminal,
a twelfth transistor of the first conductivity type connected at a first end thereof to the second end of the fourth current source, connected at a second end thereof to the noninverting output terminal, and connected at a control terminal thereof to the inverting input terminal,
a thirteenth transistor of the second conductivity type connected at a first end thereof to the first power supply rail, and connected at a control terminal thereof to the noninverting input terminal,
a fourteenth transistor of the second conductivity type connected at a first end thereof to the inverting output terminal and connected at a control terminal thereof to the inverting input terminal,
a second resistor connected between a second end of the thirteenth transistor and a second end of the fourteenth transistor,
a fifth current source connected at a first end thereof to the second end of the thirteenth transistor, connected at a second end thereof to the second power supply rail, and adapted to output a current, and
a sixth current source connected at a first end thereof to the second end of the fourteenth transistor, connected at a second end thereof to the second power supply rail, and adapted to output a current.

8. The power amplifier circuit according to claim 4, wherein the Gm amplifier comprises:
a third current source connected at a first end thereof to the first power supply rail, and adapted to output a current,
a fourth current source connected at a first end thereof to the first power supply rail, and adapted to output a current,
a first resistor connected between a second end of the third current source and a second end of the fourth current source,
an eleventh transistor of the first conductivity type connected at a first end thereof to the second end of the third current source, connected at a second end thereof to the second power supply rail, and connected at a control terminal thereof to the noninverting input terminal,
a twelfth transistor of the first conductivity type connected at a first end thereof to the second end of the fourth current source, connected at a second end thereof to the noninverting output terminal, and connected at a control terminal thereof to the inverting input terminal,
a thirteenth transistor of the second conductivity type connected at a first end thereof to the first power supply rail, and connected at a control terminal thereof to the noninverting input terminal,
a fourteenth transistor of the second conductivity type connected at a first end thereof to the inverting output terminal and connected at a control terminal thereof to the inverting input terminal,
a second resistor connected between a second end of the thirteenth transistor and a second end of the fourteenth transistor,
a fifth current source connected at a first end thereof to the second end of the thirteenth transistor, connected at a second end thereof to the second power supply rail, and adapted to output a current, and
a sixth current source connected at a first end thereof to the second end of the fourteenth transistor, connected at a second end thereof to the second power supply rail, and adapted to output a current.

9. The power amplifier circuit according to claim 1, wherein the reference voltage is an intermediate voltage between the first voltage and the second voltage.

10. The power amplifier circuit according to claim 1, wherein
the first to fourth and ninth transistors are pMOS transistors or PNP transistors,
the fifth to eighth and tenth transistors are nMOS transistors or NPN transistors,
the first voltage is a power supply voltage, and
the second voltage is a ground voltage.

11. A power amplifier circuit comprising:
a Gm amplifier supplied at a noninverting input terminal thereof with an input signal and supplied at an inverting input terminal thereof with a reference voltage;
a first current source which is connected at a first end thereof to a first power supply rail supplied with a first voltage and which outputs a first current;
a first transistor of a first conductivity type connected at a first end thereof to the first power supply rail, and connected at a second end thereof to a noninverting output terminal of the Gm amplifier;
a second transistor of the first conductivity type which is connected at a first end thereof to the first power supply rail, and through which a current obtained by current-mirroring a current flowing through the first transistor flows;
a third transistor of the first conductivity type connected at a first end thereof to a second end of the first transistor;
a fourth transistor of the first conductivity type which is connected at a first end thereof to the second end of the second transistor, and through which a current obtained by current-mirroring a current flowing through the third transistor flows;
a second current source which is connected at a first end thereof to a second end of the third transistor and connected at a second end thereof to a second power supply rail supplied with a second voltage lower than the first voltage, and which outputs a second current equivalent to the first current;
a fifth transistor of a second conductivity type which is different from the first conductivity type connected at a first end thereof to a second end of the first current source, and connected at a second end thereof to an inverting output terminal of the Gm amplifier;
a sixth transistor of the second conductivity type which is connected at a first end thereof to the second end of the second transistor and connected at a second end thereof to the second end of the fourth transistor, and through which a current obtained by current-mirroring a current flowing through the fifth transistor flows;
a seventh transistor of the second conductivity type connected at a first end thereof to a second end of the fifth transistor and connected at a second end thereof to the second power supply rail;
an eighth transistor of the second conductivity type which is connected at a first end thereof to the second end of the sixth transistor and connected at a second end thereof to the second power supply rail, and through which a current obtained by current-mirroring a current flowing through the seventh transistor flows;
a ninth transistor of the first conductivity type which is connected at a first end thereof to the first power supply rail, connected at a second end thereof to a signal output terminal for outputting an amplified signal, and connected at a control terminal thereof to the second end of the second transistor; and
a tenth transistor of the second conductivity type connected at a first end thereof to the signal output terminal, connected at a second end thereof to the second power supply rail, and connected at a control terminal thereof to the first end of the eighth transistor.

12. The power amplifier circuit according to claim 11, wherein
a current, obtained by current-mirroring a current flowing through the first transistor with a first mirror ratio, flows through the second transistor,
a current, obtained by current-mirroring a current flowing through the third transistor with the first mirror ratio, flows through the fourth transistor,
a current, obtained by current-mirroring a current flowing through the fifth transistor with the first mirror ratio, flows through the sixth transistor, and
a current, obtained by current-mirroring a current flowing through the seventh transistor with the first mirror ratio, flows through the eighth transistor.

13. The power amplifier circuit according to claim 11, wherein the Gm amplifier comprises:
a third current source connected at a first end thereof to the first power supply rail, and adapted to output a current,
an eleventh transistor of the second conductivity type connected at a first end thereof to the second end of the third current source, and connected at a second end thereof to the noninverting input terminal,
a twelfth transistor of the second conductivity type connected at a first end thereof to the noninverting output terminal, connected at a second end thereof to the inverting input terminal, and connected at a control terminal thereof to a control terminal of the eleventh transistor,
a thirteenth transistor of the first conductivity type connected at a first end thereof to the noninverting input terminal,
a fourteenth transistor of the first conductivity type connected at a first end thereof to the inverting input terminal, connected at a second end thereof to the inverting output terminal, and connected at a control terminal thereof to a control terminal of the thirteenth transistor, and
a fourth current source connected at a first end thereof to a second end of the thirteenth transistor, connected at a second end thereof to the second power supply rail, and adapted to output a current.

14. The power amplifier circuit according to claim 12, wherein the Gm amplifier comprises:
a third current source connected at a first end thereof to the first power supply rail, and adapted to output a current,
an eleventh transistor of the second conductivity type connected at a first end thereof to the second end of the third current source, and connected at a second end thereof to the noninverting input terminal,
a twelfth transistor of the second conductivity type connected at a first end thereof to the noninverting output terminal, connected at a second end thereof to the inverting input terminal, and connected at a control terminal thereof to a control terminal of the eleventh transistor,
a thirteenth transistor of the first conductivity type connected at a first end thereof to the noninverting input terminal,
a fourteenth transistor of the first conductivity type connected at a first end thereof to the inverting input terminal, connected at a second end thereof to the inverting output terminal, and connected at a control terminal thereof to a control terminal of the thirteenth transistor, and
a fourth current source connected at a first end thereof to a second end of the thirteenth transistor, connected at a second end thereof to the second power supply rail, and adapted to output a current.

15. The power amplifier circuit according to claim 11, wherein
the current flowing through the first transistor is greater than the current flowing through the inverting output terminal, and
the current flowing through the seventh transistor is greater than the current flowing through the noninverting output terminal.

16. The power amplifier circuit according to claim 12, wherein
the current flowing through the first transistor is greater than the current flowing through the inverting output terminal, and
the current flowing through the seventh transistor is greater than the current flowing through the noninverting output terminal.

17. The power amplifier circuit according to claim 13, wherein
the current flowing through the first transistor is greater than the current flowing through the inverting output terminal, and
the current flowing through the seventh transistor is greater than the current flowing through the noninverting output terminal.

18. The power amplifier circuit according to claim 11, wherein the reference voltage is an intermediate voltage between the first voltage and the second voltage.

19. The power amplifier circuit according to claim 12, wherein the reference voltage is an intermediate voltage between the first voltage and the second voltage.

20. The power amplifier circuit according to claim 11, wherein
the first to fourth and ninth transistors are pMOS transistors or PNP transistors,
the fifth to eighth and tenth transistors are nMOS transistors or NPN transistors,
the first voltage is a power supply voltage, and
the second voltage is a ground voltage.
